(19) United States
(12) Patent Application Publication
(10) Pub. No.: US 2025/0266337 A1
(43) Pub. Date: Aug. 21, 2025

(54) CIRCUIT MODULE AND MOUNTING METHOD FOR CIRCUIT MODULE

(71) Applicant: Murata Manufacturing Co., Ltd., Kyoto (JP)

(72) Inventor: Keita SATOU, Kyoto (JP)

(21) Appl. No.: 19/197,159

(22) Filed: May 2, 2025

Related U.S. Application Data
(63) Continuation of application No. PCT/JP2023/033016, filed on Sep. 11, 2023.

(30) Foreign Application Priority Data
Nov. 9, 2022 (JP) 2022-179681

(51) Int. Cl. H01L 23/498; H01L 21/48; H01L 21/56; H01L 23/31

(52) U.S. Cl. CPC H01L 23/49816; H01L 21/4853; H01L 21/4857; H01L 21/565; H01L 23/3128; H01L 23/49822

(57) ABSTRACT

A circuit module 1 includes: a substrate 11 including a first main surface 11a and a second main surface 11b; a resin layer 31 on the first main surface 11a of the substrate 11; a penetrating portion 40 penetrating the resin layer 31 in a thickness direction; and a solder bump 50 partially present in the penetrating portion 40. The circuit module 1, in a cross section including the penetrating portion 40 and the solder bump 50, taken along the thickness direction, satisfies an inequality (1) below:

Y×(X/100)>V1 (1)

wherein V1 represents an area of a gap 60 between the resin layer 31 and the solder bump 50, X represents a coefficient of thermal expansion (%) upon heating the solder bump 50 from 25° C. to 220° C., and Y represents an area of the solder bump 50.

### CROSS REFERENCE TO RELATED APPLICATION

This is a continuation of International Application No. PCT/JP2023/033016 filed on Sep. 11, 2023 which claims priority from Japanese Patent Application No. 2022-179681 filed on Nov. 9, 2022. The contents of these applications are incorporated herein by reference in their entireties.

### BACKGROUND OF THE DISCLOSURE

### 1. Field of the Disclosure

The present disclosure relates to a circuit module and a method for mounting a circuit module.

### 2. Description of the Related Art

US 2020/0043821 A discloses an example in which a package substrate includes solder bumps, and the substrate is connected to another substrate via the solder bumps (for xample, FIG. 2).

### BRIEF SUMMARY OF DISCLOSURE

Where substrates are connected to each other via solder bumps as disclosed in US 2020/0043821 A, the solder bumps are surrounded by a resin layer. FIG. 1A of US 2020/0043821 A shows gaps between solder bumps and the resin layer. In these gaps, gas generated from the solder bumps during mounting may accumulate and cause the molten solder bumps to be cut off to lead to open defects.

FIG. 1A, FIG. 1B, FIG. 1C, and FIG. 1D are schematic views showing the cause of an open defect due to gas generated from solder bumps. FIG. 1A shows a state where a solder bump 150 is in an opening of a resin layer 130 in a circuit module 100, with a gap 160 between the resin layer 130 and the solder bump 150. The width of the opening is narrower toward the outer surface of the resin layer 130. FIG. 1B shows a state where the solder bump 150 is adjacent to an electrode 210 of another substrate 200. When the solder bump 150 is heated in this state to a temperature equal to or higher than the melting point of the material constituting the solder bump 150 for mounting, due to the width of the opening being narrower toward the outer surface of the resin layer 130, as shown in FIG. 1C, gas 230 generated from the solder bump 150 is not likely to escape from the opening, thus accumulating in the gap 160 (see FIG. 1C). As shown in FIG. 1D, the gas 230 causes the solder bump 150 to be cut off and separated into a solder bump 150a on the circuit module 100 and a solder bump 150b on the other substrate 200, resulting in an open defect.

The present disclosure was made to solve the above issue and aims to provide a circuit module that is less likely to cause an open defect during mounting.

The present disclosure provides a circuit module including: a substrate including a first main surface and a second main surface; a resin layer on the first main surface of the substrate; a penetrating portion penetrating the resin layer in a thickness direction; and a solder bump partially present in the penetrating portion, the circuit module, in a cross section including the penetrating portion and the solder bump, taken along the thickness direction, satisfying an inequality (1) below:

$$Y \times ( X / 100 ) > V 1 \qquad ( 1 )$$

wherein V1 represents an area of a gap between the resin layer and the solder bump, X represents a coefficient of thermal expansion (%) upon heating the solder bump from 25° C. to 220° C., and Y represents an area of the solder bump.

The present disclosure also provides a method for mounting a circuit module, the method including heating the circuit module of the present disclosure with the circuit module placed adjacent to another substrate to melt the solder bump of the circuit module, thereby mounting the circuit module on the other substrate.

The present disclosure can provide a circuit module that is less likely to cause an open defect during mounting.

### BRIEF DESCRIPTION OF THE SEVERAL VIEWS OF THE DRAWINGS

FIG. 1A is a schematic view showing a cause of an open defect due to gas generated from a solder bump.

FIG. 1B is a schematic view showing a cause of an open defect due to gas generated from a solder bump.

FIG. 1C is a schematic view showing a cause of an open defect due to gas generated from a solder bump.

FIG. 1D is a schematic view showing a cause of an open defect due to gas generated from a solder bump.

FIG. 2 is a schematic cross-sectional view of an example circuit module according to a first embodiment.

FIG. 3 is a schematic cross-sectional view of an example cross section including a penetrating portion and a solder bump, taken along a thickness direction of a resin layer.

FIG. 4 is a schematic cross-sectional view of an example area of a gap between a resin layer and a solder bump.

FIG. 5 is a schematic cross-sectional view of an example shape of a penetrating portion.

FIG. 6 is a cross-sectional view illustrating the dimensions to be focused on around a solder bump.

FIG. 7 is a schematic cross-sectional view of another example shape of a penetrating portion.

FIG. 8 is a schematic cross-sectional view of an example embodiment in which the end of a solder bump has been flattened.

FIG. 9 is a cross-sectional view showing the size of a gap in the case of a solder bump having a flat end.

FIG. 10A is a schematic cross-sectional view of an example embodiment of the mounting of a circuit module on another substrate.

FIG. 10B is a schematic cross-sectional view of an example embodiment of the mounting of a circuit module on another substrate.

FIG. 10C is a schematic cross-sectional view of an example embodiment of the mounting of a circuit module on another substrate.

FIG. 10D is a schematic cross-sectional view of an example embodiment of the mounting of a circuit module on another substrate.

FIG. 11A is a schematic cross-sectional view of another example embodiment of the mounting of a circuit module on another substrate.

FIG. 11B is a schematic cross-sectional view of another example embodiment of the mounting of a circuit module on another substrate.

FIG. 11C is a schematic cross-sectional view of another example embodiment of the mounting of a circuit module on another substrate.

FIG. 11D is a schematic cross-sectional view of another example embodiment of the mounting of a circuit module on another substrate.

FIG. 12A is a schematic process diagram of an example process in the production of a circuit module of the present disclosure.

FIG. 12B is a schematic process diagram of an example process in the production of a circuit module of the present disclosure.

FIG. 12C is a schematic process diagram of an example process in the production of a circuit module of the present disclosure.

FIG. 12D is a schematic process diagram of an example process in the production of a circuit module of the present disclosure.

FIG. 13A is a schematic process diagram of an example process in the production of a circuit module of the present disclosure.

FIG. 13B is a schematic process diagram of an example process in the production of a circuit module of the present disclosure.

FIG. 13C is a schematic process diagram of an example process in the production of a circuit module of the present disclosure.

FIG. 14A is a schematic process diagram of an example process in the production of a circuit module of the present disclosure.

FIG. 14B is a schematic process diagram of an example process in the production of a circuit module of the present disclosure.

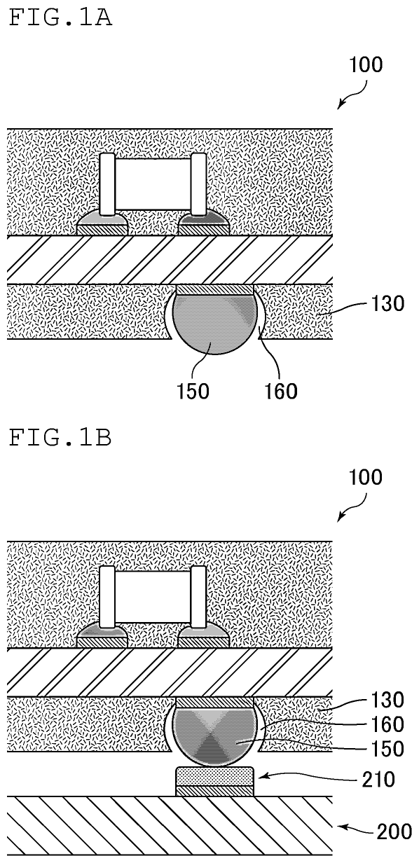

### DETAILED DESCRIPTION OF DISCLOSURE

Hereinafter, the circuit module of the present disclosure is described. The present disclosure is not limited to the following preferred embodiments, and may be suitably modified without departing from the gist of the present disclosure. Combinations of two or more preferred features described in the following preferred embodiments are also within the scope of the present disclosure.

In the circuit module of the present disclosure, the area V1 of the gap between a resin layer and a solder bump in a cross section is narrow, so that the area V1 is smaller than the area [Y×(X/100)] which increases in response to thermal expansion of the solder bump during mounting. This relationship means that the gap gets filled with the solder bump due to the thermal expansion of the solder bump during mounting, making gas less likely to accumulate in the gap. With the gap between the resin layer and the solder bump being filled, gas generated within the solder bump does not enter the gap but is released outside the solder bump without causing the molten solder bump to be cut off. With such a defined relationship between the area V1 of the gap between the resin layer and the solder bump in a cross section and the area [Y×(X/100)] which increases in response to thermal expansion of the solder bump during mounting, a circuit module can be materialized that is less likely to cause an open defect during mounting.

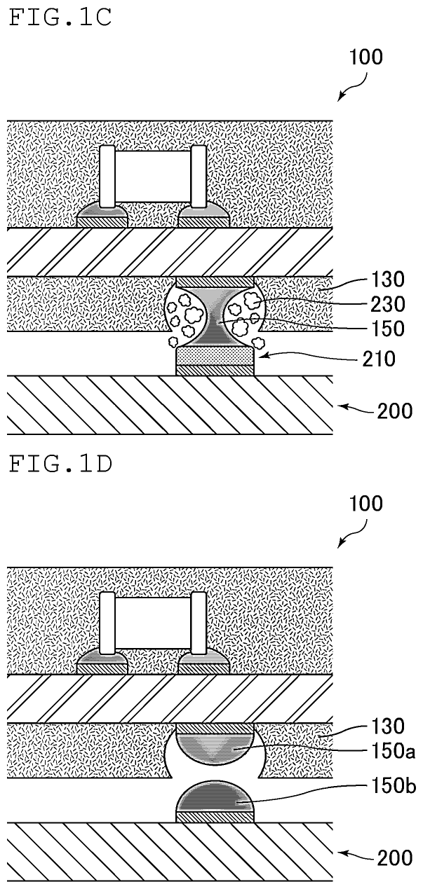

FIG. 2 is a schematic cross-sectional view of an example circuit module according to the first embodiment. A circuit module 1 includes a substrate 11, electronic components 21, a resin layer 31, and a resin layer 32.

The substrate 11 includes a first main surface 11a and a second main surface 11b opposite to each other. Electrodes 12 are on the first main surface 11a and the second main surface 11b of the substrate 11. The substrate 11 includes insulation layers 13 and essential conductors of the electronic circuit configuration, i.e., pattern conductors 14 and via conductors 15.

The substrate 11 is a ceramic substrate in which the insulation layers 13 are made of, for example, a low-temperature sintered ceramic material. The low-temperature sintered ceramic material is a type of ceramic material. It is a material that can be sintered simultaneously with silver and copper used as metal materials at a sintering temperature of 1000° C. or lower. Examples include those containing SiO₂—CaO—Al₂O₃—B₂O₃-based glass ceramic or SiO₂—MgO—Al₂O₃—B₂O₃-based glass ceramic. Yet, the type of the insulation layers 13 is not limited thereto. For example, the insulation layers 13 may be made of a glass epoxy resin, a ceramic material other than low-temperature sintered ceramic materials, glass, or the like. The pattern conductors 14 and the via conductors 15 are formed from a metal material selected from, for example, Cu, a Cu alloy, and the like. Yet, the material of the pattern conductors 14 and the via conductors 15 is not limited thereto. The substrate 11 may be either a multilayer substrate or a single layer substrate.

The electrodes 12 are formed, for example, by plating a surface of a metal material selected from Cu, a Cu alloy, and the like with a metal material selected from Ni, a Ni alloy, and the like.

Each electronic component 21 is connected via connecting members 16 to the electrodes 12 on the first main surface 11a of the substrate 11 or the second main surface 11b of the substrate 11. Preferably, the electronic components 21 are, for example, chip components such as multilayer capacitors, multilayer inductors, and various filters, and semiconductor products such as various ICs and memories. The connecting members 16 are, for example, Sn—Ag—Cu-based Pb-free solder. Yet, the material of the connecting members 16 is not limited thereto.

In FIG. 2, the electronic components 21 are on both the first main surface 11a of the substrate 11 and the second main surface 11b of the substrate 11. Yet, the electronic components 21 may be on only one of the first main surface 11a of the substrate 11 and the second main surface 11b of the substrate 11, or may not even be on the substrate 11.

Pads 45 are on the first main surface 11a of the substrate 11, and solder bumps 50 are in contact with the pads 45. The configuration around the solder bumps 50 will be described in detail later.

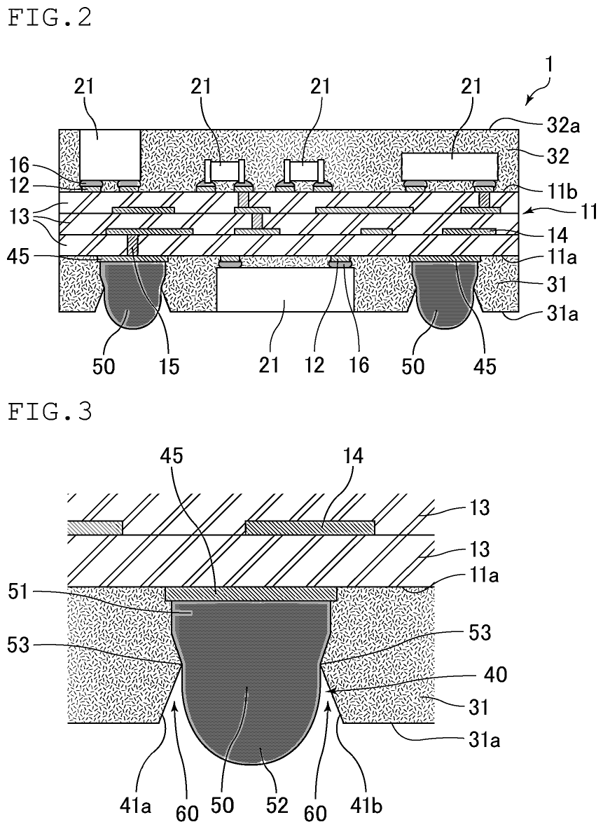

The resin layer 31 is on the first main surface 11a of the substrate 11. The resin layer 32 is on the second main surface 11b of the substrate 11. Preferably, the resin layer 31 and the resin layer 32 are each made of a resin composition in which a filler such as a glass material or silica is dispersed in a resin material. In a resin layer containing a filler, the filler in the resin layer is preferably exposed on a surface of the resin layer. The filler exposed on the surface of the resin layer can strengthen the bond between the resin layer and solder when the solder bumps melt and come into contact with the resin layer. The surface of the resin layer on which the filler is exposed here means the surface that comes into contact with a solder bump when the solder bump melts. The surface is thus not the surface indicated by the reference sign 31a in FIG. 3 but corresponds to the surfaces indicated by the reference signs 41a and 41b as the inner surfaces of the penetrating portion.

The resin layers may be layers made of only a resin material. The resin layer 31 and the resin layer 32 may be made of the same resin material or different resin materials. The circuit module of the present disclosure may not include a resin layer on the second main surface.

Each electronic component 21 may be completely covered with the resin layer 31 or the resin layer 32, or a surface of the electronic component 21 may be exposed from a surface 31a of the resin layer 31 or a surface 32a of the resin layer 32. The term “surface of the resin layer” as used herein refers to one not in contact with the substrate 11, which is one of two main surfaces opposite to each other in a thickness direction of the resin layer.

FIG. 3 is a schematic cross-sectional view of an example cross section including a penetrating portion and a solder bump, taken along a thickness direction of a resin layer. Hereinbelow, the term “cross section” alone herein means a cross section including a penetrating portion and a solder bump, taken along a thickness direction of a resin layer.

A penetrating portion 40 penetrates the resin layer 31 in the thickness direction. The pad 45 and part of the solder bump 50 are present in the penetrating portion 40. The solder bump 50 partially protrudes outward (downward in the drawing) from the surface 31a of the resin layer. The expression that the penetrating portion 40 penetrates the resin layer 31 means that, with the elements other than the resin layer 31 (the pad 45 and the solder bump 50 in FIG. 3) assumed to be removed from the resin layer 31, a through hole lies in the thickness direction of the resin layer 31. The portion corresponding to the through hole is the penetrating portion 40.

One of main surfaces of the pad 45 is in contact with the first main surface 11a of the substrate 11. The other main surface of the pad 45 is in contact with the solder bump 50. The circuit module may not include the pad in the penetrating portion, and the solder bump 50 may be in contact with an electrode exposed on the first main surface 11a of the substrate. There may also be another conductor between the pad 45 and the solder bump 50.

In the cross section, the solder bump preferably has a constriction, and the constriction preferably defines a boundary between a first bump on the substrate side and a second bump on a surface side of the resin layer. FIG. 3 shows a constriction 53 which defines a first bump 51 on the substrate 11 side and a second bump 52 on the surface 31a side of the resin layer. The position of the constriction 53 is where the inclination of the side surface of the solder bump 50 changes in the cross-sectional view.

A gap 60 is present between the solder bump 50 and the resin layer 31. The position of the gap 60 corresponds to the position between the solder bump 50 and an inner surface 41a of the penetrating portion and the position between the solder bump 50 and an inner surface 41b of the penetrating portion. In particular, in the case where the solder bump includes a first bump and a second bump, preferably, the gap is absent between the first bump and the resin layer and the gap is present between the second bump and the resin layer. FIG. 3 also shows an embodiment in which the gap is absent between the first bump 51 and the resin layer 31 and the gap 60 is present between the second bump 52 and the resin layer 31.

The circuit module of the present disclosure satisfies Inequality (1) below:

$$Y \times ( X / 100 ) > V 1 \qquad ( 1 )$$

wherein V1 represents an area of a gap between the resin layer and the solder bump, X represents a coefficient of thermal expansion (%) upon heating the solder bump from 25° C. to 220° C., and Y represents an area of the solder bump.

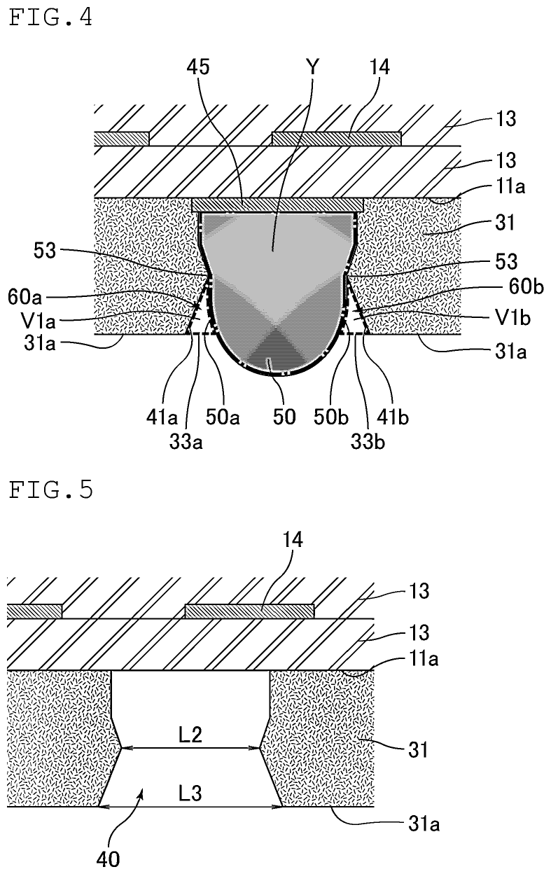

The following describes the feature above. FIG. 4 is a schematic cross-sectional view of an example area of a gap between a resin layer and a solder bump. FIG. 4 shows a gap 60a to the left of the solder bump 50 and a gap 60b to the right of the solder bump 50 in a cross-sectional view as regions surrounded by the dotted lines. FIG. 4 shows an extension line 33a indicating a line obtained by extending the surface 31a of the resin layer that is to the left of the solder bump 50 to the solder bump 50, and an extension line 33b indicating a line obtained by extending the surface 31a of the resin layer that is to the right of the solder bump 50 to the solder bump 50. The gap 60a to the left of the solder bump is the region surrounded by a surface 50a of the solder bump on the left side of the solder bump, the inner surface 41a of the penetrating portion to the left of the solder bump, and the extension line 33a. The gap 60b to the right of the solder bump is the region surrounded by a surface 50b of the solder bump on the right side of the solder bump, the inner surface 41b of the penetrating portion to the right of the solder bump, and the extension line 33b.

The area of the gap 60a in the cross-sectional view is denoted by V1a, and the area of the gap 60b is denoted by V1b. The area V1 of the gap between the resin layer and the solder bump is determined from the equation: V1=V1a+V1b.

FIG. 4 shows the solder bump 50 as the region surrounded by the dashed and dotted line. The area of the solder bump is denoted by Y. The area Y of the solder bump and the areas V1, V1a, and V1b of the gaps can be determined from a cross-sectional photograph of the circuit module including the solder bump and the resin layer. In the determination, a cross-sectional photograph of the cross section where the cross-sectional area of the solder bump is the largest is used.

The coefficient of thermal expansion (%) upon heating the solder bump from 25° C. to 220° C. is denoted by X. The coefficient of thermal expansion X is preferably 2% or higher, more preferably 3% or higher. The coefficient of thermal expansion X is preferably 5% or lower, more preferably 4% or lower. The coefficient of thermal expansion X of Pb-free solder is typically 2% or higher and 4% or lower. The solder bump is preferably made of Pb-free solder. The Pb-free solder may have a composition of Sn—Ag—Cu-based Pb-free solder (for example, a composition composed of Sn-3.0 wt & Ag-0.5 wt & Cu (SAC305)), for example. The Pb-free solder, when heated from 25° C. to 220° C., exhibits a coefficient of thermal expansion of 2.0% or higher and 5.0% or lower, for example.

The area of an additional portion resulting from the heating-induced expansion of the solder bump is represented by Y×(X/100). Here, the inequality Y×(X/100)>V1 holds. This means that the gap between the resin layer and the solder bump gets filled with the solder bump due to the thermal expansion of the solder bump during mounting, making gas less likely to accumulate in the gap. With the gap between the resin layer and the solder bump being filled, gas generated within the solder bump does not enter the gap but is released outside the solder bump without causing the molten solder bump to be cut off. With such a defined relationship between the area V1 of the gap between the resin layer and the solder bump in a cross section and the area [Y×(X/100)] which increases in response to thermal expansion of the solder bump during mounting, a circuit module can be materialized that is less likely to cause an open defect during mounting.

The area Y of the solder bump is not limited. For example, it is preferably 0.0146 mm² or greater, more preferably 0.0148 mm² or greater. It is also preferably 0.0158 mm² or smaller, more preferably 0.0156 mm² or smaller. The area V1 of the gap is not limited. For example, it is preferably 0.000303 mm² or greater, while it is preferably 0.000606 mm² or smaller. The area V1 of the gap is preferably not 0.

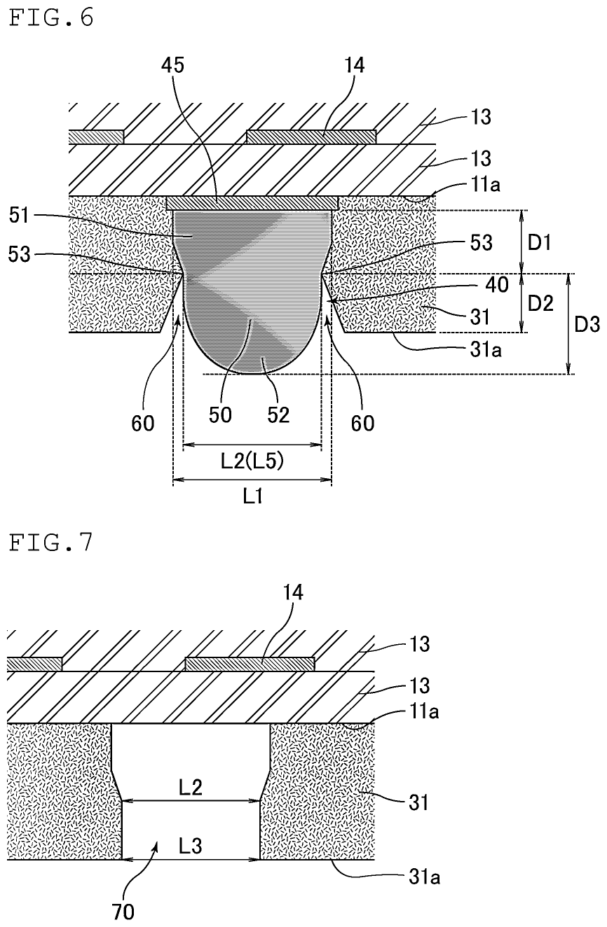

FIG. 5 is a schematic cross-sectional view of an example shape of a penetrating portion. In FIG. 5, the pad 45 and the solder bump 50 in FIG. 3 are omitted to clearly show the shape of the penetrating portion 40. In the cross section, the penetrating portion may have a tapered shape in which a width of a portion of the penetrating portion that contains the second bump is wider on the surface side of the resin layer and narrower on the substrate side along the thickness direction. FIG. 5 shows the width of the portion of the penetrating portion 40 that contains the second bump. The width thereof on the surface 31a side of the resin layer is indicated by a double-headed arrow L3. The width thereof on the substrate 11 side is indicated by a double-headed arrow L2. The width of the penetrating portion 40 satisfies the inequality L3>L2. The width of the portion of the penetrating portion 40 that contains the second bump gradually decreases from L3 to L2 along the thickness direction. With the penetrating portion having such a tapered shape, gas generated within the solder bump is less likely to accumulate in the gap and more easily escapes outside the solder bump. The width of the portion of the penetrating portion that contains the first bump is not limited.

In the case where the penetrating portion has a tapered shape, the width L3 of the penetrating portion on the surface side of the resin layer and the width L2 thereof on the substrate side are not limited. The width L3 is, for example, preferably 0.180 mm or greater, more preferably 0.190 mm or greater. It is also preferably 0.220 mm or smaller, more preferably 0.210 mm or smaller. The width L2 is, for example, preferably 0.130 mm or greater, more preferably 0.155 mm or greater. It is also preferably 0.180 mm or smaller, more preferably 0.170 mm or smaller.

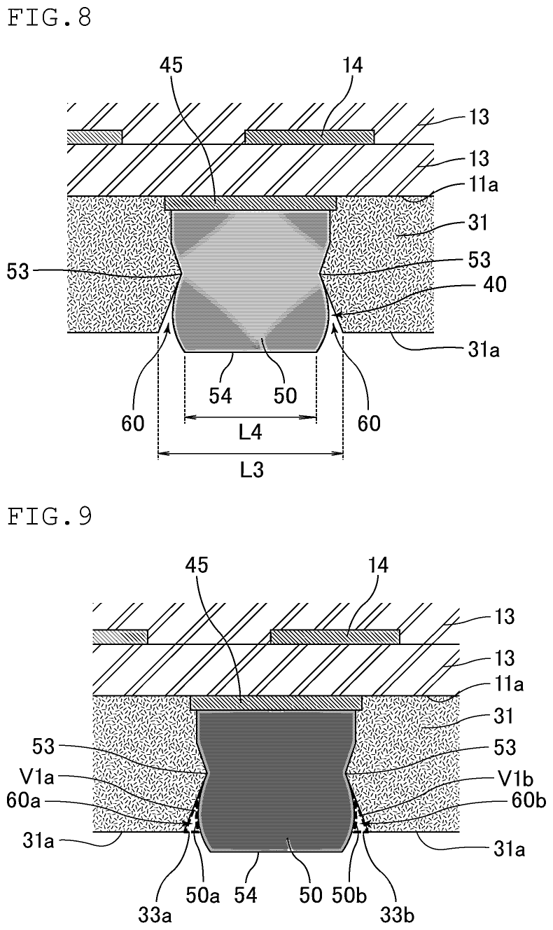

FIG. 6 is a cross-sectional view illustrating the dimensions to be focused on around a solder bump. In the cross section, the inequality D1≥D2 preferably holds, where D1 represents the height from the pad on the substrate and in contact with the solder bump to the constriction, and D2 represents the height from the constriction to the surface of the resin layer. In FIG. 6, the height in the cross section from the pad 45 on the substrate 11 and in contact with the solder bump 50 to the constriction 53 is indicated by a double-headed arrow D1, and the height from the constriction 53 to the surface 31a of the resin layer is indicated by a double-headed arrow D2. The relationship between the heights preferably satisfies the inequality D1≥D2. Such a relationship between D1 and D2 is preferred because it makes a shallow gap, further reducing the gap between the resin layer and the solder bump, so that gas generated from the solder bump is less likely to accumulate in the gap.

The height D1 from the pad to the constriction and the height D2 from the constriction to the surface of the resin layer are not limited. The height D1 is, for example, preferably 0.040 mm or greater, more preferably 0.050 mm or greater. It is also preferably 0.070 mm or smaller, more preferably 0.060 mm or smaller. The height D2 is, for example, preferably 0.025 mm or greater, while it is preferably 0.040 mm or smaller. The difference (D1-D2) between the height D1 and the height D2 is, for example, preferably 0.010 mm or more, more preferably 0.025 mm or more. It is preferably 0.045 mm or less, more preferably 0.030 mm or less.

In FIG. 6, the maximum width of the first bump is indicated by a double-headed arrow L1. Also, the width of the first bump at the positions where the gap 60 disappears on the substrate side (in FIG. 6, the same position as the constriction) is indicated by a double-headed arrow L5. The double-headed arrow L5 in the embodiment shown in FIG. 6 is the same as the width L2 of the portion of the penetrating portion that contains the second bump on the substrate side. The width L1 and the width L5 preferably satisfy the inequality L1≥L5. Such a relationship between L1 and L5 is preferred because it makes gas generated from the solder bump less likely to be trapped in the gap.

The width L1 and the width L5 of the first bump are not limited. The width L1 is, for example, preferably 0.170 mm or greater, more preferably 0.190 mm or greater. It is also preferably 0.250 mm or smaller, more preferably 0.230 mm or smaller. The width L5 is, for example, preferably 0.130 mm or greater, more preferably 0.155 mm or greater. It is also preferably 0.230 mm or smaller, more preferably 0.215 mm or smaller.

Also in FIG. 6, the height of the second bump is indicated by a double-headed arrow D3. The height of the second bump 52 in FIG. 6 is the height of the second bump 52 not having been subjected to a flattening process. The end of the second bump 52 shown in FIG. 6 is curved. The height D3 of the second bump is not limited. The height D3 is, for example, preferably 0.030 mm or greater, more preferably 0.040 mm or greater. It is also preferably 0.070 mm or smaller, more preferably 0.060 mm or smaller.

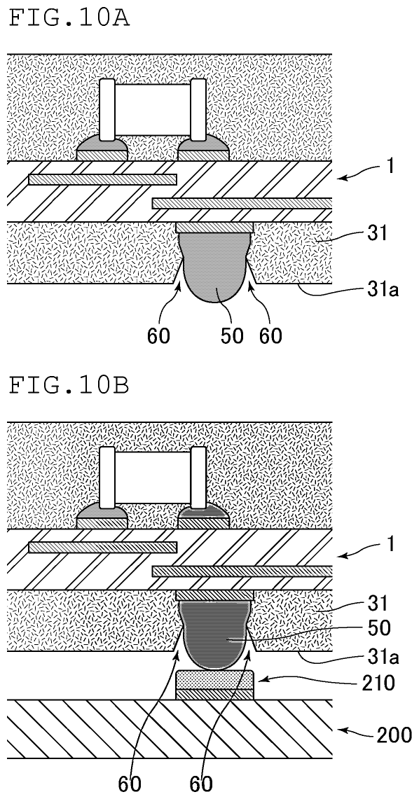

FIG. 7 is a schematic cross-sectional view of another example shape of a penetrating portion. In FIG. 7, the pad 45 and the solder bump 50 are omitted to clearly show the shape of a penetrating portion 70 as in FIG. 5. In the cross section, the width of the portion of the penetrating portion that contains the second bump may be constant between the surface side of the resin layer and the substrate side along the thickness direction. FIG. 7 shows the width of the portion of the penetrating portion 70 that contains the second bump. The width thereof on the surface 31a side of the resin layer is indicated by the double-headed arrow L3. The width thereof on the substrate 11 side is indicated by the double-headed arrow L2. The width of the penetrating portion 70 satisfies the equation L3=L2. The width of the portion of the penetrating portion 70 that contains the second bump is constant along the thickness direction. With the penetrating portion having such a constant width along the thickness direction, a gap is less likely to be left between the resin and the second bump formed therein, so that gas is even less likely to accumulate in the gap during mounting than in the case of the penetrating portion having a tapered shape. The width of the portion of the penetrating portion that contains the first bump is not limited.

The width L3 of the penetrating portion having a constant width on the surface side of the resin layer (the width L2 on the substrate side) is not limited. The width L3 and the width L2 are, for example, preferably 0.150 mm or greater, more preferably 0.165 mm or greater. They are also preferably 0.190 mm or smaller, more preferably 0.180 mm or smaller.

In the cross section, the inner surfaces of the penetrating portion may have a stepped shape, and thus the width of the penetrating portion may vary stepwise. In this case, the width of the penetrating portion is made to vary stepwise, with the width being wider on the surface side of the resin layer and narrower on the substrate side.

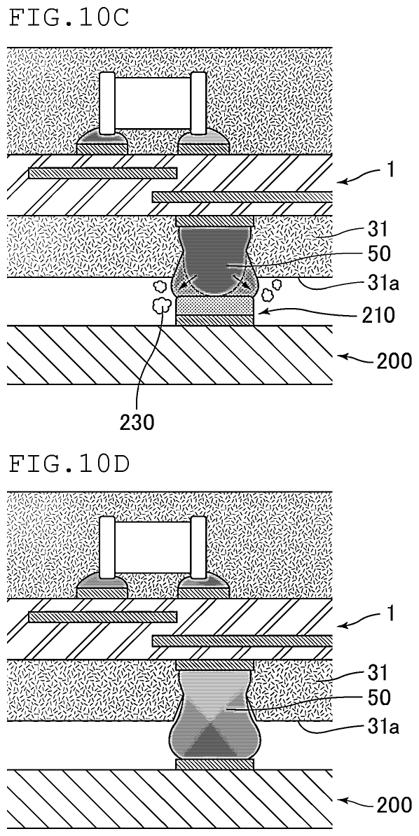

In the cross section, the end of the solder bump may be flat. Such a flat end of the solder bump increases the mountability. With the flat end of the solder bump, a width L4 of the end of the solder bump may be smaller than the width L3 of the penetrating portion at the surface of the resin layer. FIG. 8 is a schematic cross-sectional view of an example embodiment in which the end of a solder bump has been flattened. FIG. 8 shows an embodiment in which the end of the solder bump 50 has been flattened into a flat portion 54. The flat portion is formed by the coining process in the method for producing a circuit module described later. In FIG. 8, the width of the end of the solder bump (width of the flat portion) is indicated by a double-headed arrow L4, and the width of the penetrating portion at the surface of the resin layer is indicated by the double-headed arrow L3. In FIG. 8, the width L4 and the width L3 satisfy the inequality L4<L3. Such a relationship satisfying the inequality L4<L3 is preferred because a structure satisfying the inequality L4>L3 would make gas less likely to escape.

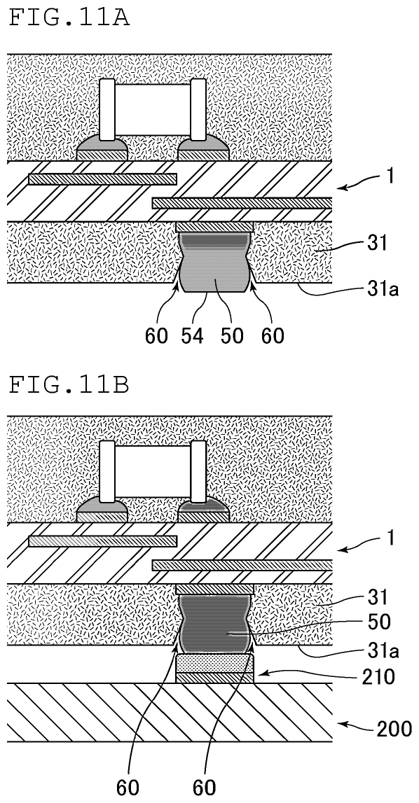

FIG. 9 is a cross-sectional view showing the size of a gap in the case of a solder bump having a flat end. FIG. 9, as with FIG. 4, shows the gap 60a to the left of the solder bump and the gap 60b to the right of the solder bump as regions surrounded by the dotted lines. The coining process of flattening the end of the solder bump pushes the second bump into the penetrating portion, changing the shape of the second bump. This makes the gap 60a and the gap 60b smaller, so that the area V1a of the gap 60a and the area V1b of the gap 60b become smaller than the area V1a and the area V1b shown in FIG. 4. The area V1 of the gap between the resin layer and the solder bump also becomes smaller than the area V1 shown in FIG. 4. With a small area V1 of the gap between the resin layer and the solder bump, gas generated within the solder bump is less likely to enter the gap between the resin layer and the solder bump but is more likely to be released outside the solder bump. Thus, a circuit module can be materialized that is less likely to cause an open defect during mounting. In other words, the coining process of flattening the end of the solder bump enables a circuit module that is even less likely to cause an open defect during mounting.

The following describes a method for mounting the circuit module of the present disclosure on another substrate. The method for mounting a circuit module of the present disclosure includes heating the circuit module with the circuit module placed adjacent to another substrate to melt the solder bump of the circuit module, thereby mounting the circuit module on the other substrate.

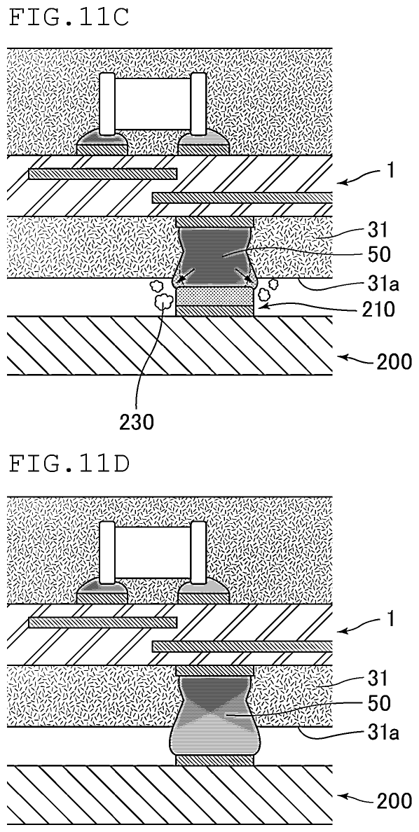

FIG. 10A, FIG. 10B, FIG. 10C, and FIG. 10D are each a schematic cross-sectional view of an example embodiment of the mounting of a circuit module on another substrate. FIG. 10A shows part of the circuit module including a solder bump. In the circuit module 1 shown in FIG. 10A, the solder bump 50 protrudes outward (downward in the drawing) from the surface 31a of the resin layer. The gap 60 is present between the solder bump 50 and the resin layer 31.

FIG. 10B shows a state where the solder bump 50 is placed adjacent to the electrode 210 of the other substrate 200. The solder bump 50 is heated in this state to a temperature equal to or higher than the melting point of the material constituting the solder bump 50 for mounting. The heating, as shown in FIG. 10C, causes the gas 230 to be generated from the solder bump 50, but simultaneously melts the solder bump, causing it to expand thermally and thereby to fill the gap 60. The gas 230 generated within the solder bump 50 is therefore released outside the solder bump 50 without entering the gap 60. The solder bump 50 is not cut off due to the gas 230, so that as shown in FIG. 10D, the circuit module 1 and the other substrate 200 are connected by the solder bump 50. This connection does not cause an open defect. In this manner, the circuit module 1 is mounted on the other substrate 200.

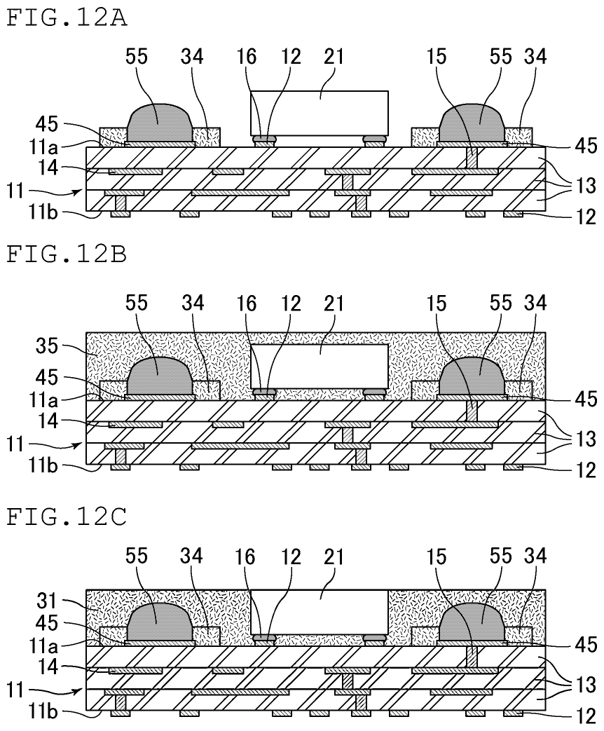

FIG. 11A, FIG. 11B, FIG. 11C, and FIG. 11D are each a schematic cross-sectional view of another example embodiment of the mounting of a circuit module on another substrate. FIG. 11A shows part of the circuit module including a solder bump. The end of the solder bump 50 has been flattened into the flat portion 54 by the coining process. The area of the gap 60 is smaller than the area of the gap 60 shown in FIG. 10A.

FIG. 11B shows a state where the solder bump 50 is placed adjacent to the electrode 210 of the other substrate 200. The solder bump 50 is heated in this state to a temperature equal to or higher than the melting point of the material constituting the solder bump 50 for mounting. The heating, as shown in FIG. 11C, causes the gas 230 to be generated from the solder bump 50, but simultaneously melts the solder bump, causing it to expand thermally and thereby to fill the gap 60. The gas 230 generated within the solder bump 50 is therefore released outside the solder bump 50 without entering the gap 60. The solder bump 50 is not cut off due to the gas 230, so that as shown in FIG. 11D, the circuit module 1 and the other substrate 200 are connected by the solder bump 50. This connection does not cause an open defect. In this manner, the circuit module 1 is mounted on the other substrate 200.

The area of the gap 60 in the circuit module shown in FIG. 11A is smaller than the area of the gap 60 in the circuit module shown in FIG. 10A. Although there is a small gap between the solder bump and the resin layer after the mounting in FIG. 10D, the solder bump and the resin layer are in close contact with each other without any gap in between after the mounting in FIG. 11D. In other words, in the case where the end of the solder bump has been flattened into a flat portion by the coining process, the area of the gap between the solder bump and the resin layer is further reduced, so that the likelihood of open defects is further decreased.

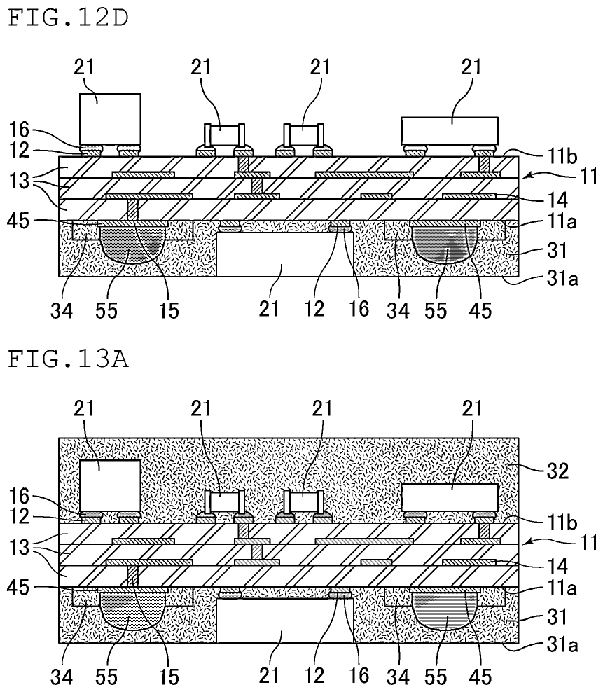

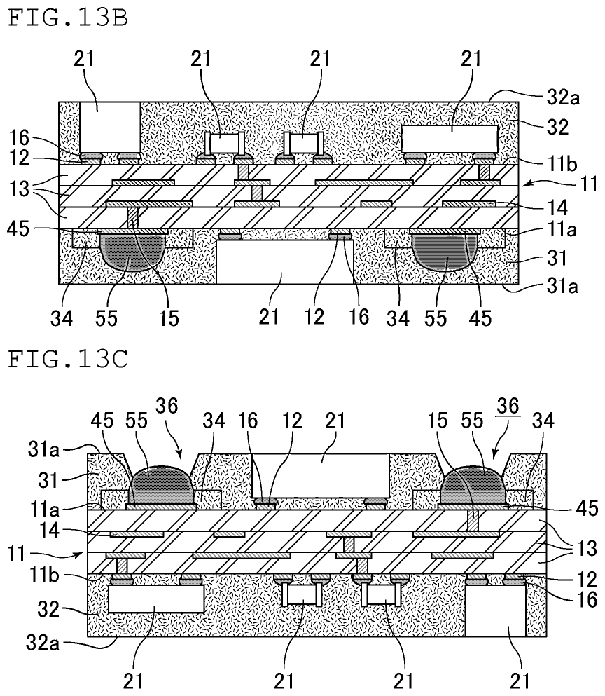

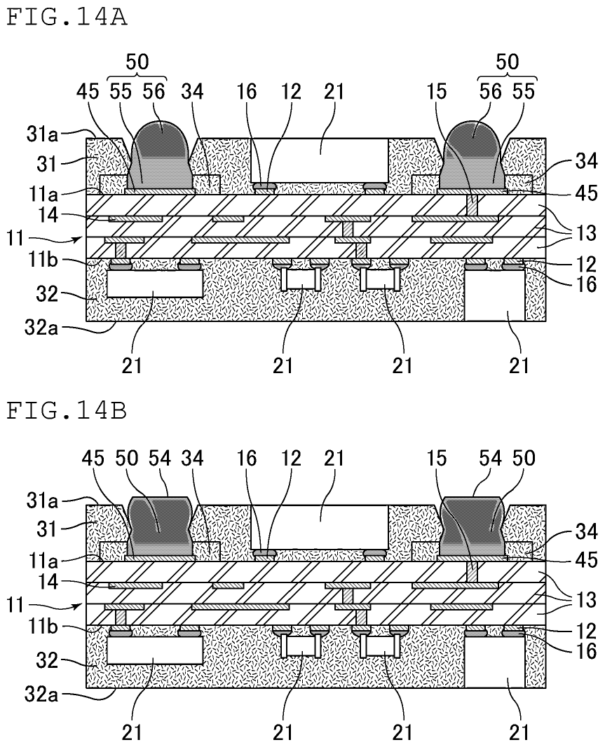

The following describes an example method for producing a circuit module of the present disclosure. FIG. 12A, FIG. 12B, FIG. 12C, FIG. 12D, FIG. 13A, FIG. 13B, FIG. 13C, FIG. 14A, and FIG. 14B are each a schematic process diagram of an example process in the production of a circuit module of the present disclosure. The processes after solder bumps are formed in the production of a circuit module are described below. FIG. 12A shows a state where the pads 45 are formed on the first main surface 11a of the substrate 11, a lower layer resin layer 34 is formed around the pads 45, and lower layer solder bumps 55 are formed in openings formed in the lower layer resin layer 34. The openings can be formed in the lower layer resin layer 34 by laser processing or the like, and the lower layer solder bumps 55 can be formed by applying solder paste in the openings by printing. Formation of the lower layer solder bumps 55 in the openings in the lower layer resin layer 34 by printing brings the lower layer resin layer 34 and the lower layer solder bumps 55 in close contact with each other, achieving a state where there is no gap between the lower layer resin layer 34 and the lower layer solder bumps 55.

As shown in FIG. 12B, a sealing resin layer 35 is formed on the first main surface 11a of the substrate 11. The sealing resin layer 35 preferably covers the electronic component 21. The sealing resin layer 35 and the lower layer resin layer 34 may be made of the same material or different materials. The sealing resin layer 35 and the lower layer resin layer 34, if made of the same material, form an integrated resin layer and no distinction is made therebetween. The sealing resin layer 35 may be formed without formation of the lower layer resin layer 34. As shown in FIG. 12C, the surface is ground to expose the surface of the electronic component 21.

The workpiece is then turned over, so that the electronic components 21 are formed on the second main surface 11b of the substrate 11 as shown in FIG. 12D, and a resin layer 32 (sealing resin layer) is formed on the second main surface 11b of the substrate 11 as shown in FIG. 13A. In addition, as shown in FIG. 13B, the surface is ground to expose the surfaces of the electronic components 21.

The workpiece is then turned over again, and as shown in FIG. 13C, openings 36 are formed in the sealing resin layer 35 to expose the lower layer solder bumps 55. The openings 36 may be formed in the sealing resin layer 35 by laser processing or the like. FIG. 13C shows a state where the tapered openings 36 are formed by laser processing.

As shown in FIG. 14A, solder paste is applied to the openings 36 by printing and subjected to the reflow process to form upper layer solder bumps 56. The upper layer solder bumps 56 and the lower layer solder bumps 55 are integrated into the solder bumps 50. The thus-formed solder bumps 50 have the constriction 53. The processes above enable production of the circuit module of the present disclosure.

The heights to the top surfaces of the upper layer solder bumps 56 formed by the reflow process often vary. The solder bumps 56 may thus be subjected to the coining process for flattening. FIG. 14B shows a state where the ends of the solder bumps 50 have been formed into the flat portions 54 by the coining process. The coining process makes the area of the gap 60 between each solder bump 50 and the resin layer 31 smaller than the area of the gap 60 before the coining process. This can further decrease the likelihood of open defects during mounting.

The present description discloses the following.

### Disclosure <1>

A circuit module including: a substrate including a first main surface and a second main surface; a resin layer on the first main surface of the substrate; a penetrating portion penetrating the resin layer in a thickness direction; and a solder bump partially present in the penetrating portion, the circuit module, in a cross section including the penetrating portion and the solder bump, taken along the thickness direction, satisfying an inequality (1) below:

$$Y \times ( X / 100 ) > V 1 \qquad ( 1 )$$

wherein V1 represents an area of a gap between the resin layer and the solder bump, X represents a coefficient of thermal expansion (%) upon heating the solder bump from 25° C. to 220° C., and Y represents an area of the solder bump.

### Disclosure <2>

The circuit module according to Disclosure <1>, wherein in the cross section, the solder bump has a constriction, and the constriction defines a boundary between a first bump on a substrate side and a second bump on a surface side of the resin layer.

### Disclosure <3>

The circuit module according to Disclosure <2>, wherein in the cross section, the gap is absent between the first bump and the resin layer and the gap is present between the second bump and the resin layer.

### Disclosure <4>

The circuit module according to Disclosure <2> or <3>, wherein in the cross section, the penetrating portion has a tapered shape in which a width of a portion of the penetrating portion that contains the second bump is wider on the surface side of the resin layer and narrower on the substrate side along the thickness direction.

### Disclosure <5>

The circuit module according to Disclosure <2> or <3>, wherein in the cross section, a width of a portion of the penetrating portion that contains the second bump is constant between the surface side of the resin layer and the substrate side along the thickness direction.

### Disclosure <6>

The circuit module according to any one of Disclosures <2> to <5>, wherein in the cross section, an inequality D1≥D2 holds, where D1 represents a height from a pad on the substrate and in contact with the solder bump to the constriction, and D2 represents a height from the constriction to the surface of the resin layer.

### Disclosure <7>

The circuit module according to any one of Disclosures <1> to <6>, wherein a filler in the resin layer is exposed on a surface of the resin layer.

### Disclosure <8>

The circuit module according to any one of Disclosures <1> to <7>, wherein an end of the solder bump is flat.

### Disclosure <9>

The circuit module according to Disclosure <8>, wherein in the cross section, a width L4 of the end of the solder bump is less than a width L3 of the penetrating portion at a surface of the resin layer.

### Disclosure <10>

A method for mounting a circuit module, the method including heating the circuit module according to any one of Disclosures <1> to <9> with the circuit module placed adjacent to another substrate to melt the solder bump of the circuit module, thereby mounting the circuit module on the other substrate.
1, 100 circuit module
11 substrate
11a first main surface of substrate
11b second main surface of substrate
12 electrode
13 insulation layer
14 pattern conductor
15 via conductor
16 connecting member
21 electronic component
31, 32, 130 resin layer
31a, 32a surface of resin layer
33a, 33b extension line of surface 31a of resin layer
34 lower layer resin layer
35 sealing resin layer
36 opening in sealing resin layer
40, 70 penetrating portion
41a, 41b inner surface of penetrating portion
45 pad
50, 150, 150a, 150b solder bump
50a, 50b surface of solder bump
51 first bump
52 second bump
53 constriction
54 flat portion of end of solder bump
55 lower layer solder bump
56 upper layer solder bump
60, 60a, 60b, 160 gap
200 second substrate
210 electrode of second substrate
230 gas

1. A circuit module comprising:
a substrate including a first main surface and a second main surface;
a resin layer on the first main surface of the substrate;
a penetrating portion penetrating the resin layer in a thickness direction; and
a solder bump partially present in the penetrating portion,
the circuit module, in a cross section including the penetrating portion and the solder bump, taken along the thickness direction, satisfying an inequality (1) below:
$$Y \times ( X / 100 ) > V 1 \qquad ( 1 )$$
wherein V1 represents an area of a gap between the resin layer and the solder bump, X represents a coefficient of thermal expansion (%) upon heating the solder bump from 25° C. to 220° C., and Y represents an area of the solder bump.

2. The circuit module according to claim 1,
wherein in the cross section, the solder bump has a constriction, and
the constriction defines a boundary between a first bump on a substrate side and a second bump on a surface side of the resin layer.

3. The circuit module according to claim 2,
wherein in the cross section, the gap is absent between the first bump and the resin layer and the gap is present between the second bump and the resin layer.

4. The circuit module according to claim 2,
wherein in the cross section, the penetrating portion has a tapered shape in which a width of a portion of the penetrating portion containing the second bump is wider on the surface side of the resin layer and narrower on the substrate side along the thickness direction.

5. The circuit module according to claim 2,
wherein in the cross section, a width of a portion of the penetrating portion containing the second bump is constant between the surface side of the resin layer and the substrate side along the thickness direction.

6. The circuit module according to claim 2,
wherein in the cross section, an inequality D1≥D2 holds, where D1 represents a height from a pad on the substrate and in contact with the solder bump to the constriction, and D2 represents a height from the constriction to the surface of the resin layer.

7. The circuit module according to claim 1,
wherein a filler in the resin layer is exposed on a surface of the resin layer.

8. The circuit module according to claim 1,
wherein an end of the solder bump is flat.

9. The circuit module according to claim 8,
wherein in the cross section, a width L4 of the end of the solder bump is less than a width L3 of the penetrating portion at a surface of the resin layer.

10. A method for mounting a circuit module, the method comprising:
heating the circuit module according to claim 1 with the circuit module placed adjacent to another substrate to melt the solder bump of the circuit module, thereby mounting the circuit module on the other substrate.

11. The circuit module according to claim 3,
wherein in the cross section, the penetrating portion has a tapered shape in which a width of a portion of the penetrating portion containing the second bump is wider on the surface side of the resin layer and narrower on the substrate side along the thickness direction.

12. The circuit module according to claim 3,
wherein in the cross section, a width of a portion of the penetrating portion containing the second bump is constant between the surface side of the resin layer and the substrate side along the thickness direction.

13. The circuit module according to claim 3,
wherein in the cross section, an inequality D1≥D2 holds, where D1 represents a height from a pad on the substrate and in contact with the solder bump to the constriction, and D2 represents a height from the constriction to the surface of the resin layer.

14. The circuit module according to claim 4,
wherein in the cross section, an inequality D1≥D2 holds, where D1 represents a height from a pad on the substrate and in contact with the solder bump to the constriction, and D2 represents a height from the 5 constriction to the surface of the resin layer.

15. The circuit module according to claim 5,
wherein in the cross section, an inequality D1≥D2 holds, where D1 represents a height from a pad on the substrate and in contact with the solder bump to the constriction, and D2 represents a height from the constriction to the surface of the resin layer.

16. The circuit module according to claim 2,
wherein a filler in the resin layer is exposed on a surface of the resin layer.

17. The circuit module according to claim 3,
wherein a filler in the resin layer is exposed on a surface of the resin layer.

18. The circuit module according to claim 4,
wherein a filler in the resin layer is exposed on a surface of the resin layer.

19. The circuit module according to claim 5,
wherein a filler in the resin layer is exposed on a surface of the resin layer.

20. The circuit module according to claim 6,
wherein a filler in the resin layer is exposed on a surface of the resin layer.
